(19) United States
(12) Patent Application Publication
(10) Pub. No.: US 2011/0155230 A1
(43) Pub. Date: Jun. 30, 2011

(54) MULTI-BANDGAP SOLAR CELL AND METHOD PRODUCING THE SAME

(75) Inventors: Hung-Chun Tsai, Hsinchu City (TW); Chi-Lai Lee, Pingzhen City (TW); Yu-Ting Lin, Hsinchu City (TW); Yaw-Ming Tsai, Wuri Township (TW)

(73) Assignee: Du Pont Apollo Limited, Pak Shek Kok (HK)

(21) Appl. No.: 12/965,591

(22) Filed: Dec. 10, 2010

Related U.S. Application Data
(60) Provisional application No. 61/290,295, filed on Dec. 28, 2009.

(51) Int. Cl. H01L 31/06; H01L 31/18

(52) U.S. Cl. 136/255; 438/73; 257/E31.001

(57) ABSTRACT

A multi-bandgap solar cell is produced by using a transparent intercellular layer to bind two solar cells with different bandgaps. The intercellular layer has at least an adhesive layer.

### RELATED APPLICATIONS

This application claims priority to U.S. Provisional Application Ser. No. 61/290,295, filed Dec. 28, 2009, which is herein incorporated by reference.

### BACKGROUND

1. Technical Field

The disclosure relates to solar cells. More particularly, the disclosure relates to multi-bandgap solar cells.

2. Description of Related Art

It is well known that the most efficient conversion of radiant energy to electrical energy with the least thermalization loss in semiconductor materials is accomplished by matching the photon energy of the incident radiation to the amount of energy needed to excite electrons in the semiconductor material to transcend the bandgap from the valence band to the conduction band. However, since solar radiation usually comprises a wide range of wavelengths, use of only one semiconductor material with one band gap to absorb such radiant energy and convert it to electrical energy results in large inefficiencies and energy losses to unwanted heat. Accordingly, the benefits of using tandem solar cells incorporating both wide bandgap and narrow bandgap materials have been recognized.

### SUMMARY

Accordingly, a multi-bandgap solar cell is provided. The multi-band-gap solar cell is produced by using a transparent intercellular layer to bind two solar cells with different bandgaps. The intercellular layer is hermetic to prevent oxygen and moisture from penetrating the intercellular layer to the solar cells. The breakdown voltage of the intercellular layer is higher than 6000 V.

According to an embodiment, the intercellular layer has at least an adhesive layer.

According to another embodiment, the intercellular layer sequentially has at least a first adhesive layer, a central layer, and a second adhesive layer, wherein the central layer is a transparent dielectric layer.

The material of the adhesive layer can be polyethylene terephthalate (PET), ethylene vinyl acetate (EVA), polyvinyl butyral (PVB), poly(ethylene naphtalate)

(PEN), cyclic olefin copolymer-poly(methyl methacrylate) (COC.PMMA), polycarbonate (PC), polystyrene (PS), polyethylene (PE), or polypropylene (PP), for example.

### BRIEF DESCRIPTION OF THE DRAWINGS

FIGS. 1A-1B are cross-sectional diagram of a multi-bandgap solar cell according to an embodiment of this invention.

FIGS. 2A-2B are cross-sectional diagram of a multi-bandgap solar cell according to another embodiment of this invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In an embodiment, a first solar cell and a second solar cell are bound via a transparent intercellular layer. The intercellular layer has good adhesive strength to both the first and second solar cells. Moreover, the intercellular layer is an insulator with breakdown voltage larger than about 6000 V for preventing any leakage current between the first and second solar cells. For better reliability of solar cell, the intercellular layer is hermetic to prevent oxygen and moisture from penetrating to the solar cells. The intercellular layer could be manufactured by using lamination process to form a multiple-layer film.

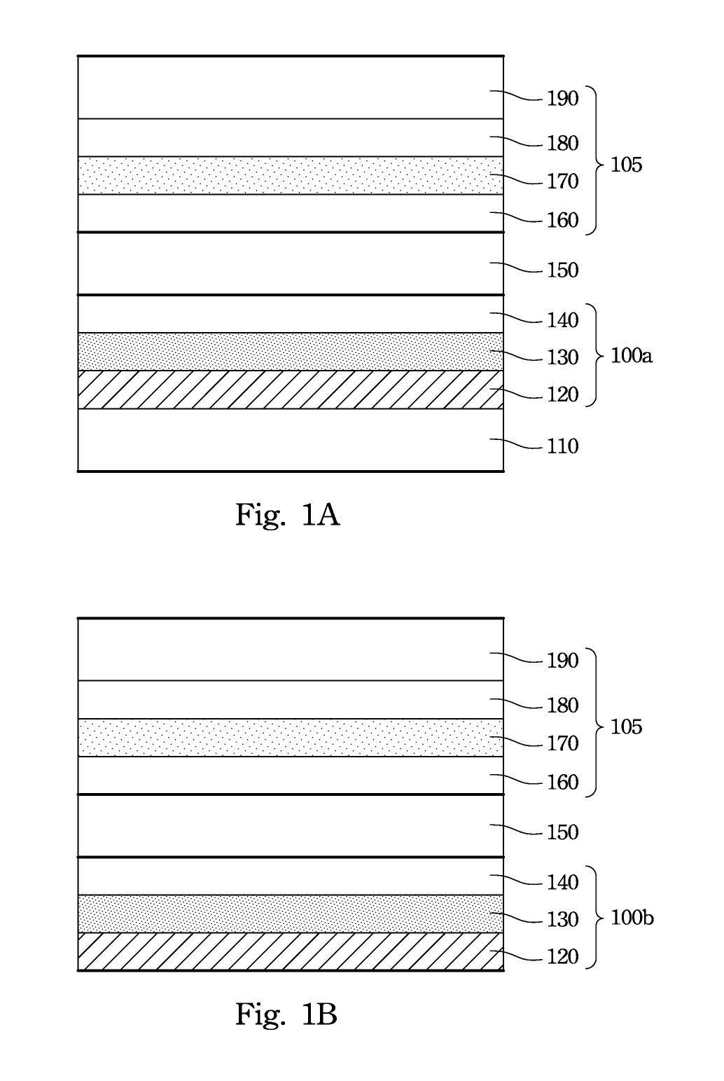

FIGS. 1A-1B are cross-sectional diagram of a multi-bandgap solar cell according to an embodiment of this invention.

In FIG. 1A, a first solar cell 100a and a second solar cell 105 of the superstrate-type structure are bound via a transparent intercellular layer 150. The intercellular layer 150 can be one adhesive layer or multiple adhesive layers, for example. The material of the intercellular layer 150 can be PET, EVA, PVB, PEN, COC.PMMA, PC, PS, PE, PP for example.

The first solar cell 100a located under the intercellular layer 150 sequentially has a first substrate 110, a first electrode 120, a first semiconductor layer 130, and a second transparent electrode 140. The second transparent electrode 140 directly contacts with the intercellular layer 150.

The second solar cell 105 above the intercellular layer 150 sequentially has a third transparent electrode 160, a second semiconductor layer 170, and a fourth transparent electrode 180, and a second transparent substrate 190. The third transparent electrode 160 directly contacts with the intercellular layer 150.

The first semiconductor layer 130 and the second semiconductor layer 170 above respectively have a first bandgap and a second bandgap, and the first bandgap is smaller than the second bandgap. The material of the first semiconductor layer 130 and the second semiconductor layer 170 can be silicon, cooper indium gallium selenide (CIGS), CdTe, or an organic material such as C₆₀, PEDOT:PSS-Poly(3,4-ethylenedioxythiophene), magnesium phthalocyanine (MgPh), poly[2-methoxy-5-(2′-ethyl-hexyloxy)-1,4-phenylene vinylene] (MEH-PPV), or a photosensitive dye such as ruthenium-polypyridine dye, for example. The silicon above can be amorphous silicon, or poly silicon.

The first substrate 110 and the second substrate 190 mentioned above can be glass substrate, for example. The material of the first, second, third, and fourth electrodes 120, 140, 160, and 180 above is transparent conductive material, such as PbO₂, CdO, TI₂O₃, Ga₂O₃, ZnPb₂O₆, CdIn₂O₄, MgIn₂O₄, ZnGaO₄, AgSbO₃, CuAlO₂, CuGaO₂, CdO-GeO₂, AZO (ZnO:Al), GZO (ZnO:Ga), ATO (SnO₂:Sb), FTO (SnO₂:F), ITO (In₂O₃:Sn), or BaTiO₃, for example.

However, since the light entering site is at the second substrate 190, the layers, i.e. the first electrode 120 and the first substrate 110, below the second semiconductor layer 130 can be opaque. For example, the material of the first electrode 120 can be metal.

In FIG. 1B, the structure is basically the same as that in FIG. 1A except that the first solar cell 100b has a substrate-type structure. In other words, the substrate 110 in FIG. 1A can be omitted, and the first electrode 120 in FIG. 1B is a metal electrode.

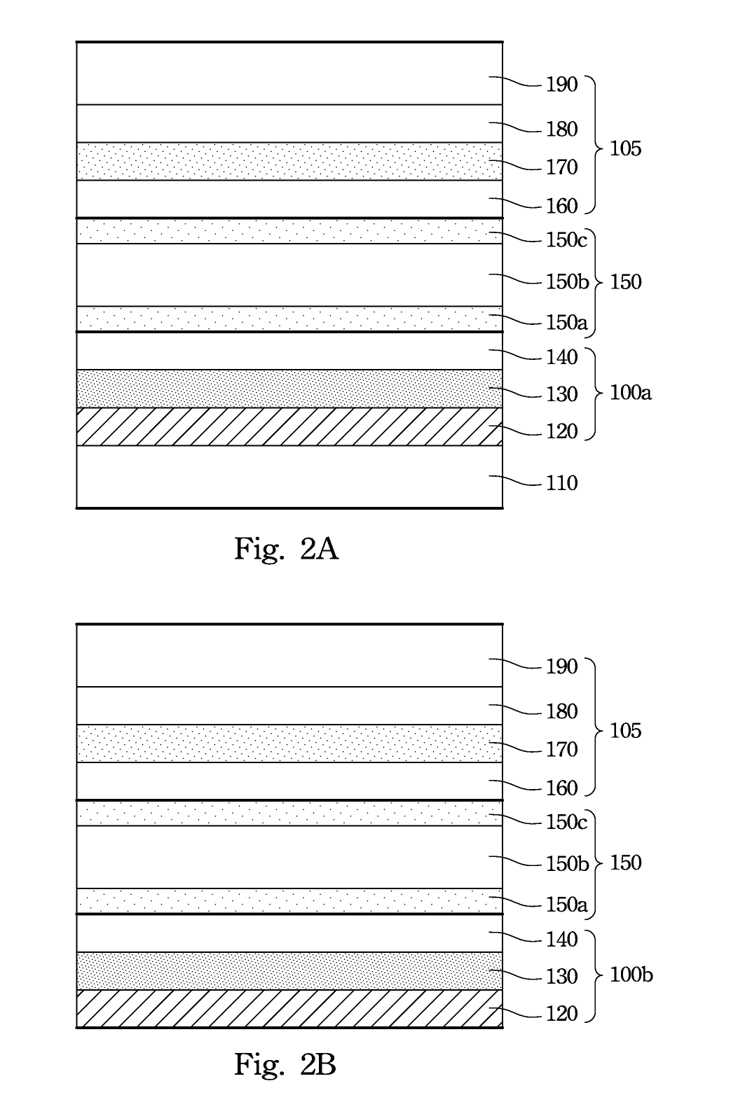

FIGS. 2A-2B are cross-sectional diagram of a multi-bandgap solar cell according to another embodiment of this invention. The structures in FIGS. 2A-2B are respectively the same as those in FIGS. 1A and 1B except that the intercellular layer 155 in FIGS. 2A-2B has at least a 3-layer structure.

In FIGS. 2A-2B, the intercellular layer 150 sequentially has a first adhesive layer 150a, a central layer 150b, and a second adhesive layer 150c. The layer structures of each of the first adhesive layer 150a, the central layer 150b, and the second adhesive layer 150c can be a single-layer structure or a multiple-layer structure.

The material of the first and the second adhesive layers 150a and 150c can be PET, EVA, PVB, PEN, COC.PMMA, PC, PS, PE, PP for example. The material of the central layer 150b is a dielectric material, such as silicon oxide, silicon nitride, silicon carbide, silicon oxynitride, oxygen doped silicon carbide nitrogen doped silicon carbide, aluminum oxide, or a combination thereof, for example. Three-layer structure could provide better adhesion to the first and the second solar cells and better properties to prevent any leakage current and oxygen/moisture penetration into the solar cell. Accordingly, since the first and the second solar cells can be separately produced without interference with each other, the problems of integrating two solar cell as one module such as leakage current and reliability issues can be solved.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A multi-bandgap solar cell, comprising:
a first solar cell having a first bandgap;
a transparent intercellular layer on the first solar cell, wherein the intercellular layer has a breakdown voltage higher than 6000 V and is an insulator to prevent oxygen and moisture from penetrating the intercellular layer, and the intercellular layer comprises at least an adhesive layer; and
a second solar cell on the intercellular layer, wherein the second solar cell has a second bandgap, and the second bandgap is larger than the first bandgap.

2. The multi-bandgap solar cell of claim 1, wherein the adhesive layer is polyethylene terephthalate (PET), ethylene vinyl acetate (EVA), polyvinyl butyral (PVB), poly(ethylene naphtalate) (PEN), cyclic olefin copolymer-poly(methyl methacrylate) (COC.PMMA), polycarbonate (PC), polystyrene (PS), polyethylene (PE), or polypropylene (PP).

3. The multi-bandgap solar cell of claim 1, wherein the transparent intercellular layer comprises:
a first adhesive layer;
a central layer on the first adhesive layer, wherein the central layer is a transparent dielectric layer; and
a second adhesive layer on the central layer.

4. The multi-bandgap solar cell of claim 3, wherein the central layer is silicon oxide, silicon nitride, silicon carbide, silicon oxynitride, oxygen doped silicon carbide, nitrogen doped silicon carbide, aluminum oxide, or a combination thereof.

5. A method of producing a multi-bandgap solar cell, the method comprising:
producing a first solar cell having a first bandgap;
producing a second solar cell having a second bandgap, wherein the second bandgap is larger than the first bandgap; and
binding the first solar cell and the second solar cell via a transparent intercellular layer, wherein the intercellular layer has a breakdown voltage higher than 6000 V and is an insulator to prevent oxygen and moisture from penetrating the intercellular layer, and the intercellular layer comprises at least an adhesive layer.

6. The method of claim 5, wherein the adhesive layer is polyethylene terephthalate (PET), ethylene vinyl acetate (EVA), polyvinyl butyral (PVB), poly(ethylene naphtalate) (PEN), cyclic olefin copolymer-poly(methyl methacrylate) (COC.PMMA), polycarbonate (PC), polystyrene (PS), polyethylene (PE), or polypropylene (PP).

7. The method of claim 5, wherein the transparent intercellular layer comprises:
a first adhesive layer;
a central layer on the first adhesive layer; and
a second adhesive layer on the central layer.

8. The method of claim 7, wherein the central layer is silicon oxide, silicon nitride, silicon carbide, silicon oxynitride, oxygen doped silicon carbide, nitrogen doped silicon carbide, aluminum oxide, or a combination thereof.
